(19) United States
(12) Patent Application Publication
(10) Pub. No.: US 2014/0197325 A1
(43) Pub. Date: Jul. 17, 2014

(54) CHARGED PARTICLE BEAM LENS AND EXPOSURE APPARATUS USING THE SAME

(71) Applicants: Takahisa Kato, Brookline, MA (US); Yutaka Setomoto, Tokyo (JP)

(72) Inventors: Takahisa Kato, Brookline, MA (US); Yutaka Setomoto, Tokyo (JP)

(73) Assignee: CANON KABUSHIKI KAISHA, Tokyo (JP)

(21) Appl. No.: 14/005,078

(22) PCT Filed: Mar. 14, 2012
(86) PCT No.: PCT/JP2012/001781

§ 371 Date: Feb. 25, 2014

(30) Foreign Application Priority Data
Mar. 15, 2011 (JP) 2011-056814

(51) Int. Cl. H01J 37/12; H01J 3/18

(52) U.S. Cl. CPC H01J 37/12; H01J 3/18
USPC 250/396 R

(57) ABSTRACT

An electrostatic charged particle beam lens includes an electrode including a flat plate having a first surface having a normal line extending in a direction of an optical axis and a second surface opposite to the first surface, the electrode having a through-hole extending from the first surface to the second surface. When an opening cross section is defined as a cross section of the through-hole taken along a plane perpendicular to the normal line and a representative diameter is defined as a diameter of a circle obtained by performing regression analysis of the opening cross section, a representative diameter of the opening cross section in a first region that is on the first surface side and a representative diameter of the opening cross section in a second region that is on the second surface side are each larger than a representative diameter of the opening cross section in a third region that is a region in the electrode disposed between the first surface and the second surface.

### TECHNICAL FIELD

The present invention relates to the technical field of electron optical systems that are used in apparatuses using a charged particle beam such as an electron beam. In particular, the present invention relates to an electron optical system that is used in an exposure apparatus. In the present invention, the term “light” refers not only to visible light but also to electromagnetic radiation such as an electron beam or the like.

### BACKGROUND ART

In the production of semiconductor devices, electron beam exposure technology is a promising lithography technology that enables exposure of a fine pattern with a width of 0.1 micrometers or smaller. In electron beam exposure apparatuses, an electron optical element is used to control optical characteristics of an electron beam. Electron lenses are classified into an electromagnetic type and an electrostatic type. The structure of an electrostatic electron lens is simpler than that of an electromagnetic electron lens because an electrostatic electron lens does not have a coil core. Therefore, the electrostatic type is advantageous in reduction in size. Regarding the electron beam exposure technology, multi-beam systems, which form a pattern by simultaneously using a plurality of electron beams instead of using a mask, have been proposed. A multi-beam system includes an electron lens array in which electron lenses are arranged one dimensionally or two dimensionally. In the electron beam lithography technology, the limit of microfabrication is not determined by the diffraction limit of an electron beam but by optical aberrations of an electron optical element. Therefore, it is important to realize an electron optical element having small aberrations.

PTL 1 describes an electrostatic lens apparatus including a plurality of electrode substrates each having an opening disposed in a plane perpendicular to an optical axis and the electrode substrates are assembled while adjusting the positions of the openings.

### CITATION LIST

### Patent Literature

PTL 1: Japanese Patent Laid-Open No. 2007-019194

### SUMMARY OF INVENTION

### Technical Problem

An electrostatic charged particle beam lens has a structure simpler than that of an electromagnetic lens. However, optical aberrations of an electrostatic charged particle beam lens are highly sensitive to a fabrication error of an opening of the lens. In particular, when the opening is circular, astigmatism of the lens is sensitive to the symmetry of the shape of the opening, such as the circularity (deviation of a circular shape from a perfect circle) of the opening. An electron beam that is converged under the influence of an asymmetric opening has astigmatism or another high order aberration.

In particular, this problem is important when a plurality of electron beams having different astigmatisms is used, because such astigmatisms cannot be corrected by using an ordinary stigmator.

According to an aspect of the present invention, an electrostatic charged particle beam lens includes an electrode including a flat plate having a first surface having a normal line extending in a direction of an optical axis and a second surface opposite to the first surface, the electrode having a through-hole extending from the first surface to the second surface. When an opening cross section is defined as a cross section of the through-hole taken along a plane perpendicular to the normal line and a representative diameter is defined as a diameter of a circle obtained by performing regression analysis of the opening cross section, a representative diameter of the opening cross section in a first region that is on the first surface side and a representative diameter of the opening cross section in a second region that is on the second surface side are each larger than a representative diameter of the opening cross section in a third region that is a region in the electrode disposed between the first surface and the second surface.

### Advantageous Effects of Invention

With the charged particle beam lens according to the present invention, by segmenting the opening into the first, second, and third regions and by making the representative diameters of the opening in the first and second regions be larger than that in the third region, the contributions of the opening cross sections in the first and second regions to the aberration of the lens can be reduced. The opening in the first and second regions includes the outermost surfaces of the electrode. Even if the opening cross sections at such positions are damaged or foreign substances adhere to the opening cross sections, increase in the aberration of the lens can be restrained.

### BRIEF DESCRIPTION OF DRAWINGS

FIG. 1 is a sectional view of a charged particle beam lens according to a first embodiment of the present invention.

FIG. 2A is a top view of an opening of the charged particle beam lens according to the first embodiment of the present invention.

FIG. 2B is a sectional view taken along line IIB-IIB of FIG. 2A.

FIG. 3A is a sectional view of an opening according to an existing technology.

FIG. 3B is a sectional view of an opening according to the first embodiment of the present invention.

FIG. 4 is a graph illustrating the contribution of the openings in the first and second regions to the aberration according to the present invention.

FIG. 5 is a sectional view of a charged particle beam lens according to a second embodiment of the present invention.

FIG. 6 is a conceptual diagram illustrating the convergence effect of an electrostatic charged particle beam lens.

FIG. 7 is a diagram illustrating the distribution of potential in the vicinity of an opening of the charged particle beam lens.

FIG. 8A is a conceptual diagram illustrating the definition of the circularity of an opening cross section.

FIG. 8B is a conceptual diagram illustrating the definition of the circularity of an opening cross section.

FIG. 8C is a conceptual diagram illustrating the definition of the circularity of an opening cross section.

FIG. 8D is a conceptual diagram illustrating the definition of the circularity of an opening cross section.

FIG. 8E is a conceptual diagram illustrating the definition of the circularity of an opening cross section.

FIG. 8F is a conceptual diagram illustrating the definition of the circularity of an opening cross section.

FIG. 9 is a sectional view of a charged particle beam lens according to a third embodiment of the present invention.

FIG. 10 is a conceptual diagram illustrating a lithography system according to a fourth embodiment of the present invention.

FIG. 11A is a conceptual diagram illustrating the definition of the representative diameter and the representative radius of an opening cross section.

FIG. 11B is a conceptual diagram illustrating the definition of the representative diameter and the representative radius of an opening cross section.

FIG. 11C is a conceptual diagram illustrating the definition of the representative diameter and the representative radius of an opening cross section.

FIG. 12 is a conceptual diagram illustrating the definition of representative diameters along the thickness direction.

### DESCRIPTION OF EMBODIMENTS

In the present invention, the terms “first surface” and “second surface” respectively refer to one of the surfaces (front surface) and the other surface (back surface) of an electrode of a charged particle beam lens according the present invention. The terms “first region”, “second region”, and “third region” refer to three segments of the electrode having predetermined thicknesses in the thickness direction.

In the charged particle beam lens according to the present invention, an opening is segmented into first, second, and third regions, and the representative diameters of the opening in the first and second region is larger than the representative diameter of the opening in the third region, and thereby the contribution of the opening cross sections in the first and second regions to the aberration of the lens can be reduced. The opening in the first and second regions includes the outermost surfaces of the electrode. Even if the opening cross sections at such positions are damaged or foreign substances adhere to the opening cross sections, increase in the aberration of the lens can be restrained. Therefore, the yield of forming an opening in the electrode is improved and additional steps for protection are not necessary, so that the lens can be manufactured at low cost. Moreover, even if the opening cross sections at such positions are damaged or foreign substances adhere to the opening cross sections, increase in the aberration of the lens can be restrained. Furthermore, because the thickness of the entirety of the electrode is only negligibly changed even when the first and second regions are formed, the electrode may have a high rigidity. Therefore, when the electrode is used in a lens to which strong electric field is applied, the amount of deformation of the electrode due to electrostatic attraction can be reduced.

In the charged particle beam lens according to the present invention, an opening cross section in the third region, which has a large influence on the aberration of the lens, may be formed with a high circularity. With such a structure, the charged particle beam lens may have a small aberration. Moreover, the opening in the first and second regions may be formed by using a method having a large fabrication tolerance while allowing a small breakage to occur during a manufacturing process. As a result, the yield is improved and the lens can be manufacture at low cost.

In charged particle beam lens according to the present invention, the thicknesses of the first and second regions may be smaller than that of the third region. In this case, the contribution of the first and second regions to the aberration can be made further smaller than that of that of the third region. Thus, even if the circularities of the first and second regions become substantially worse, increase in the aberration can be restrained.

In the charged particle beam lens according to the present invention, the sum of the aberrations of the openings in the first and second region may be lower equal to or lower than 80% of the aberration of the entirety of the electrode. With such a structure, the circularities of the openings in the first and second regions may be allowed to be equal to or larger than ½ of the circularity of the opening in the third region. If the contribution of the first and second region does not exceed the value described above, the opening cross section in the first and second regions can be formed easily in an actual manufacturing process.

With the charged particle beam lens according to the present invention, a step of forming openings in the first and second regions, for which high precision is required, may be performed independently of a step of forming an opening in the third region. By doing so, by using semiconductor manufacturing technologies, fine and high precision openings can be formed while improving controllability of etching conditions and the yield. In particular, an electrode having a finer opening can be formed with high precision by using microfabrication technologies, such as photolithography or dry etching, and wafer bonding through silicon wafers having high degree of flatness. The thicknesses of the first to third regions can be precisely formed. As necessary, the electrode may have a stacked structure in which a plurality of wafers are bonded. For example, because precision of forming an opening generally decreases as the thickness of a wafer increases, the thickness of a single wafer may be determined in accordance with a required precision (the thickness is reduced when higher precision is required). In this case, if the thickness of the entirety of the electrode becomes insufficient, a plurality of wafers may be stacked. Instead of stacking wafers, an electrode may be formed by depositing necessary layers by using, for example, a spattering method, a CVD method, a vapor-phase or liquid phase epitaxial growth method, or a plating method.

With the charged particle beam lens according to the present invention, even if breakage occurs up to an opening cross section near the interface between the first or second region and the third region, increase in the aberration of the lens can be restrained. Moreover, an opening may be formed in the first and second regions independently of forming an opening in the third region, so that the openings can be easily formed.

With the charged particle beam lens according to the present invention, fluctuation of a charged particle beam due to an unintentional charge can be prevented by covering the entirety of the electrode with an electroconductive film as necessary and thereby maintaining the potential of the electrode to be constant.

The charged particle beam lens according to the present invention may be formed as a charged particle beam lens array including an electrode having a plurality of openings. In this case, although the plurality of openings are formed in a region having a large area, the effective thickness of the entirety of the electrode for maintaining the rigidity of the electrode is not reduced, so that breakage of the opening cross sections in the first and second regions and deterioration of the circularity due to adherence of foreign substances can be tolerated. Because all of openings have such tolerance, the yield of the lens array is improved and increase in the aberration can be restrained. In the case of a lens array, it is difficult to correct the circularity of each of the individual lenses because the circularity has a random error. However, because variation in the circularity of the opening cross section can be reduced by using the present invention, necessity for individual correction can be eliminated or considerably reduced even for a large-scale lens array. Moreover, when an electrode having a bonding structure is used, variation in the opening cross sections can be sufficiently reduced. If the alignment precision of bonding is low, displacement between the openings of the first and second regions occurs. However, this displacement can be easily corrected because it is a systematic displacement in the entirety of the lens array. Therefore, this structure is appropriate for a large-scale lens array.

An exposure apparatus according to the present invention includes the charged particle beam lens according to the present invention having a small aberration, so that the exposure apparatus can form a fine pattern with high precision. Moreover, because an inexpensive lens can be used, the exposure apparatus can be produced at low cost. Furthermore, because the exposure apparatus has a large tolerance regarding foreign substances or dust that adhere to the outermost surfaces during installation or in use, maintenance can be performed easily, frequency of maintenance can be reduced, and the reliability can be improved.

The exposure apparatus according to the present invention may use a plurality of charged particle beams by using the charged particle beam lens according to the present invention having a small aberration, so that the exposure apparatus can form a fine pattern with high precision in a short time. Even when the number of arrays in the lens array is increased and the area in which the openings are formed is increased, reduction in the yield of the lens array is prevented and thereby the exposure apparatus can be manufactured at low cost.

### EMBODIMENTS

Hereinafter, embodiments of the present invention will be described in detail. However, the present invention is not limited to these embodiments.

### First Embodiment

Referring to the drawing, a first embodiment of the present invention will be described.

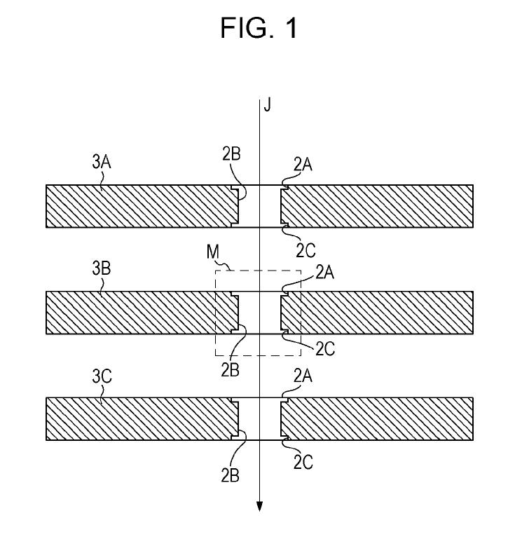

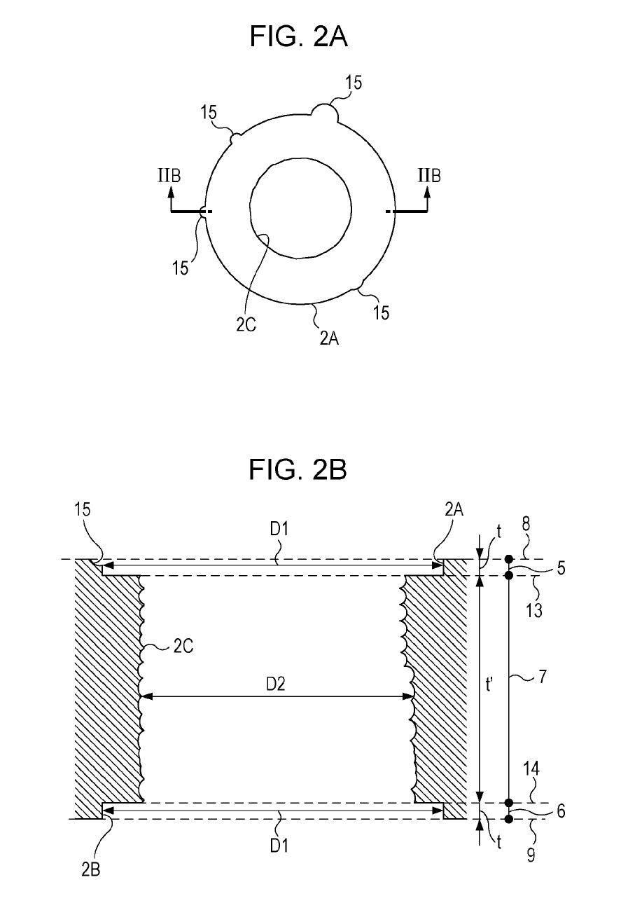

FIG. 1 is a sectional view charged particle beam lens according to the present invention. FIGS. 2A and 2B are respectively an enlarged top view and an enlarged sectional view of an opening cross section of an electrode 3B surrounded broken line M of FIG. 1. FIG. 2B is a sectional view taken along line IIB-IIB of FIG. 2A.

As illustrated in FIG. 1, the charged particle beam lens according to the present invention includes three electrodes 3A, 3B, and 3C. Each of the three electrodes is a flat plate having the optical axis J as a normal line and including a first surface and a second surface opposite to the first surface. The electrodes are electrically insulated from one another. The first surface is typically the front surface of an electrode, and the second surface is typically the back surface of an electrode. Here, the terms “front” and “back” are used only to denote a relative relationship for convenience. The potential of each of the electrodes 3A, 3B, and 3C can be controlled. A charged particle beam emitted from a beam source (not shown) passes along the optical axis J in the direction indicated by an arrow.

As illustrated in FIG. 2B, which shows an example of the structure of the electrode 3B, each of the three electrodes includes at least a first region 5, a second region 6, and a third region 7 disposed between the first and second regions. Here, it is assumed that a thickness of an electrode is the length of the electrode in the direction of the optical axis J. As illustrated in FIG. 2B, the first region 5 includes the first surface 8, which is a surface of the electrode on the beam source side with respect to the direction of the optical axis J, and has a predetermined thickness. Likewise, the second region 6 includes the second surface 9, which is a surface of the electrode on a side opposite to the beam source side with respect to the direction of the optical axis J, and has a predetermined thickness. The third region 7, which is disposed between the first and second regions, is the remaining region of the electrode and has a predetermined thickness.

As illustrated in FIG. 2B, the first, second, and third regions 5, 6, and 7 are respectively defined by the diameters of the openings 2A, 2B, and 2C. As illustrated in FIG. 1, the openings 2A, 2B, and 2C are through-holes extending through the electrodes in the thickness direction. A charged particle beam can pass through the openings. As illustrated in FIG. 2A, the opening 2A has a circular shape. Likewise, when an opening cross section is defined as a section of an opening taken along a plane having the optical axis J as a normal line, opening cross sections of the openings 2B and 2C have circular shapes that are substantially concentric with that of the opening 2A. The diameter of the opening cross section of the opening 2C is larger than those of the opening cross sections of the openings 2A and 2B. Therefore, as illustrated in FIG. 2B, the through-hole formed in each of the electrodes 3A, 3B, and 3C has a profile such that the diameter thereof is larger at the entrance and the exit. Here, the optical axis extends in a direction in which the electron beam passes.

As illustrated in FIG. 2A, the opening 2A has a chip 15. This is an example of breakage caused due to unintentional contact or the like that occurred on the outermost surface of the electrode during a manufacturing process. Instead of the chip 15, adherence of foreign substances or dust may occur. If this occurs, the deviation of the opening 2A from a perfect circle may increase in the manufacturing process.

As illustrated in FIG. 2B, the opening 2A, 2B, and 2C respectively have representative diameters D1, D1, and D2. As described above the diameters D1 and D2 satisfy a relationship D1>D2. The thickness of each of the openings 2A and 2B is t and the thickness of the opening 2C is t′. At an interface 13 between the openings 2A and 2C, the representative diameters of the opening cross sections of the openings 2A and 2C are different from each other. Likewise, at an interface 14 between the openings 2B and 2C, the representative diameters of the opening cross sections of the openings 2B and 2C are different from each other.

For example, a so-called einzel electrostatic lens is formed by applying a negative static voltage to the electrode 3B while maintaining the potential of the electrodes 3A and 3C at the ground potential. In the present invention, the term “einzel electrostatic lens” refers to an electrostatic lens in which a plurality of (typically, three) electrodes are arranged with predetermined intervals therebetween and in which the potential of outermost electrodes are maintained at the ground potential and a positive or negative potential is applied to other electrodes. When three electrodes are used, the first and the third electrodes from the incident side of a charged particle beam are maintained at the ground potential, and a positive or negative potential is applied to the second electrode. A charged particle beam is subjected to a lens effect while the beam successively passes through the openings in the electrodes 3A, 3B, and 3C. At this time, an electrostatic attraction force is generated between the electrodes 3A and 3B or between the electrodes 3B and 3C.

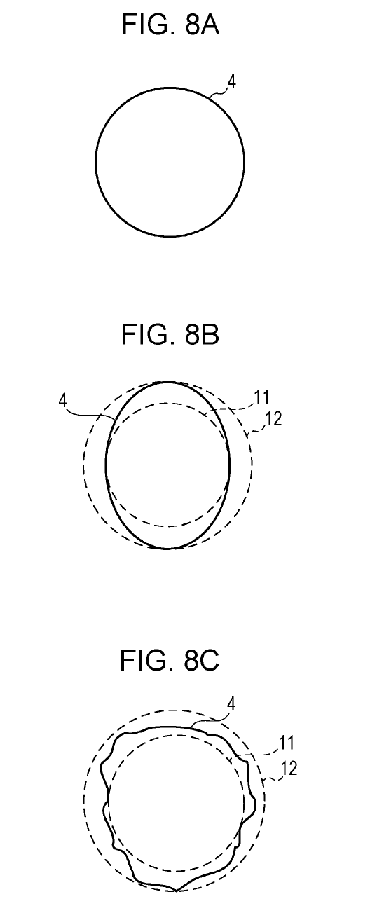

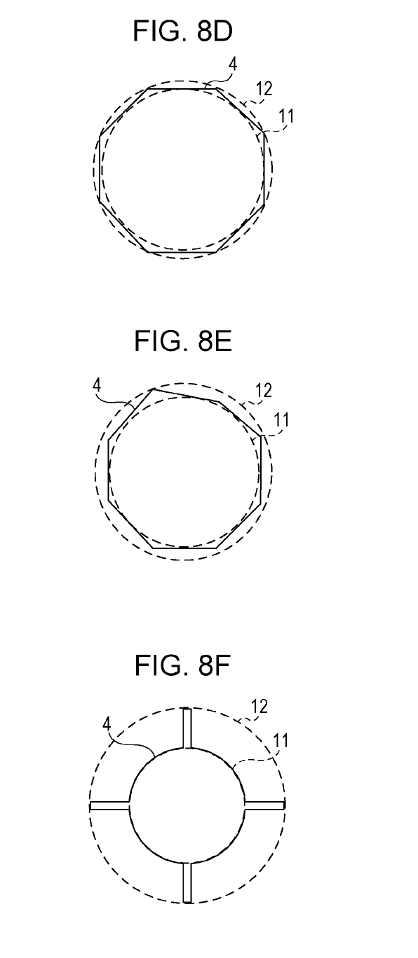

First, referring to FIGS. 8A to 8F, the definition of the symmetry of an opening cross section, which is necessary for describing a charged particle beam lens according to the present invention, will be described. An electrostatic field that generates a lens effect of an electrostatic charged particle beam lens is formed by the opening cross section. In particular, because astigmatism and higher order aberrations are generated due to rotational asymmetry around the optical axis J, deviation from a perfect circle is an important index.

FIG. 8A illustrates an opening cross section 4 having an ideally circular shape. Here, an opening cross section is a closed curve that is the intersection of the opening and a plane having the optical axis J as a normal line. The opening cross section can be defined at any position along the thickness direction. FIG. 8B illustrates an opening cross section 4 having an elliptical shape. The following index is defined as a measure of a shape error that influences the astigmatism and higher order aberrations of a charged particle beam lens according to the present invention. The opening cross section 4 illustrated in FIG. 8B, which has an elliptical shape, is disposed between two concentric circles so as to be in contact with the concentric circles. The inner circle will be referred to as an incircle 11, and the outer circle will be referred to as a circumcircle 12. Among many combinations of such concentric circles that can be drawn around different centers, a pair of an incircle and a circumcircle between which the difference in the radii thereof is the smallest are selected. The circularity is defined as a half the difference in the radii of the incircle and the circumcircle that are selected in this way. For the opening cross section 4 having a perfectly circular shape as illustrated in FIG. 8A, the circularity is zero because the circumcircle and the incircle coincide with each other.

As illustrated in FIG. 8C, the circularity is defined in a similar manner for any shapes other than ellipse.

The ideal shape in terms of design may not be a circular shape but a polygonal shape as illustrated in FIG. 8D. (An octagonal shape used as an example in the following description.) In this case, the circularity, the representative radius (described below), and the representative diameter (described below) are defined by the following method. That is, deviation of symmetry from an ideal octagon and the size of the opening can be compared by defining the circularity, the representative radius, and the representative diameter. FIG. 8D illustrates the circumcircle 12 and the incircle 11 of an ideal octagon. In the case of an octagon, the circularity is equal to or larger than zero even in an ideal state. FIG. 8E illustrates the circumcircle 12 and the incircle 11 of an octagon that has a shape error and that is deviated from a regular octagon. Therefore, the circularity in the case of FIG. 8E is larger than that of FIG. 8D, which is the case of a regular octagon.

The circularity can be defined by actually measuring the sectional shape. The sectional shape can be calculated by dividing the perimeter into a sufficiently large number of segments and obtaining the circumcircle 12 and the incircle 11 through image processing.

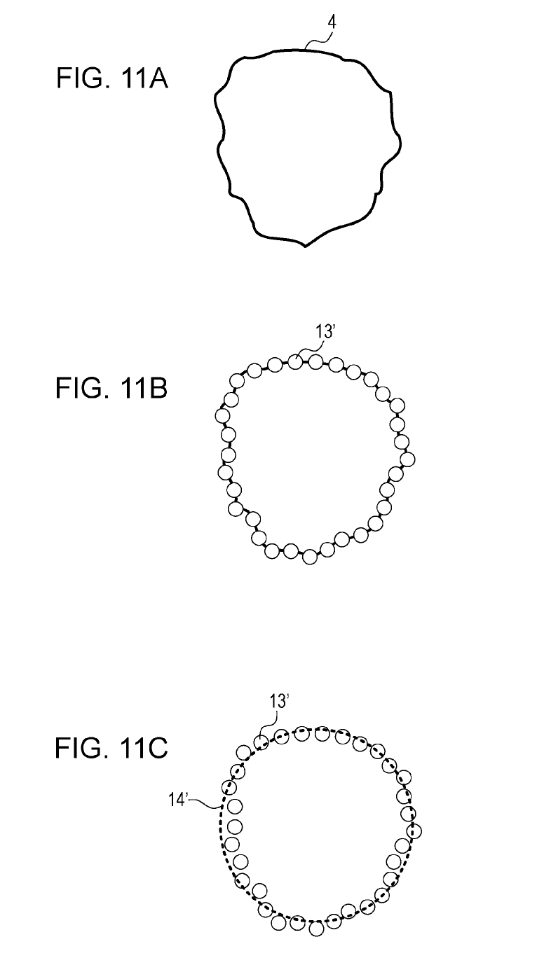

Here, the above-mentioned representative diameter and the representative radius are defined as follows. FIGS. 11A to 11C illustrate steps for determining the representative diameter of an opening cross section 4 of FIG. 8C. The outline of the opening cross section 4 of FIG. 11A is measured as a set of discrete measurement points 13′ that are spaced apart from each other with sufficiently small intervals therebetween as illustrated in FIG. 11B. The intervals may be smaller than half the representative period of the asperity of the opening cross section 4. By using the measurement points 13′ having been measured in this way, a representative circle 14′ is uniquely determined as illustrated in FIG. 11C. Regression analysis is performed by using the measurement points 13′ so that these points are geometrically fitted to an equation of a circle. The regression analysis may be performed by using a maximum likelihood method. If the measurement points 13′ are measured with sufficiently small intervals, the method of least squares can be used. The representative diameter and the representative radius are defined as the diameter and the radius of the representative circle 14′ that is determined in this way. The representative diameter and the representative radius of a representative circle are important as the representative shape that determines the distribution in the potential on or near the optical axis, because a charged particle beam passes through the center of the opening.

FIG. 8F illustrates an opening cross section 4 most parts of which are circular and the remaining parts have protruding shapes. Even in this case, the representative diameter and the representative radius can be obtained by determining a representative circle, which is a representative shape that contributes to the electric field in the vicinity of the optical axis, by using the method described above. When such a circle is obtained, the circumcircle 12 and the incircle 11 are defined by drawing circles that are concentric with the circle that has been obtained by performing geometric fitting.

The first, second, and third regions each have a thickness. The circularity, the representative diameter, and the representative radius in each of the regions in the thickness direction can be defined as follows.

The circularity of an opening cross section in the first to third regions in the thickness direction will be described.

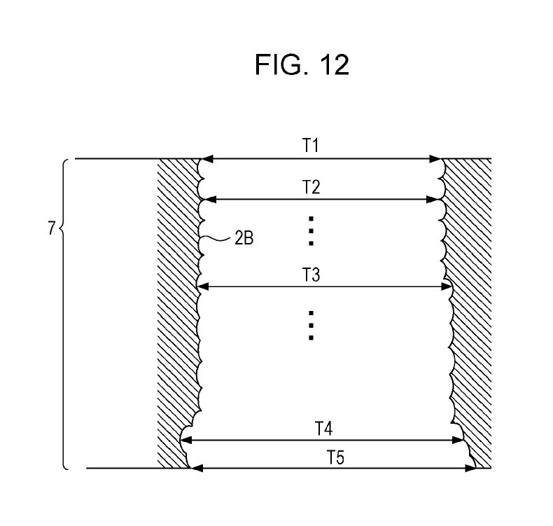

FIG. 12 illustrates the third region 7 in which the diameter and the circularity have distributions in the thickness direction. As indicated by arrows T1 to T5 in FIG. 12, opening cross sections can be defined at any positions along the depth direction. The representative diameter and the circularity describe above can be defined for each of these opening cross sections. Here, the representative diameter and the circularity of the third region 7 can be defined in this way at any positions in the depth direction of the opening. The representative diameter and the circularity of a part of the region excluding the outermost surface can be measured by temporarily backfilling the opening with plating or the like and polishing and then observing the opening. Alternatively, instead of performing such direct measurement, measurements of the outermost surface may be used as the representative value. Parts of the first to third regions other than the outermost surfaces are those that contribute to the aberration with a smaller degree. Therefore, as compared with the outermost surfaces, change in the representative diameter and the circularity of these parts in the same order of magnitude influences the aberration with a smaller degree. Therefore, if the measured values of the representative diameter and the circularity at several sections of the opening in the thickness direction are not significantly different from each other (for example, the distribution of the values does not include outliers having a different order of magnitude), the average of the representative diameters and the circularities at the outermost surfaces (i.e., at positions T1 and T5 in FIG. 12) can be used as the representative value.

On the basis of the definition described above, the circularity, the representative radius, and the representative diameter are defined for an arbitrary opening cross section. Hereinafter, a circle is used as the ideal shape of an opening cross section. However, the ideal shape may be an octagon or any other curve. Also in such cases, the circularity, the representative radius, the representative diameter can be defined and used in the present invention.

Next, the effect of opening cross sections in the first and second regions on the aberration according to the present invention will be described in detail.

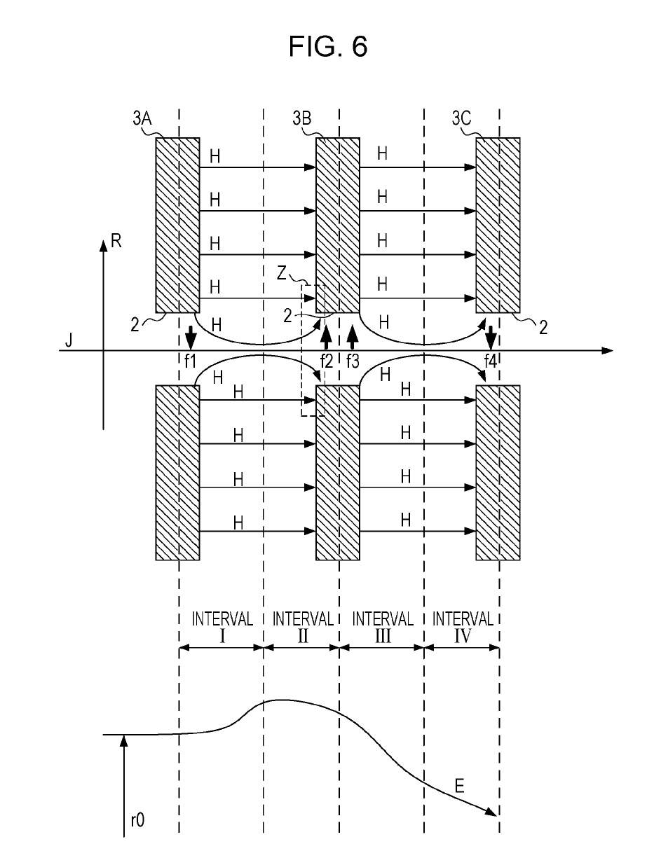

First, referring to FIG. 6, mechanisms with which an electrostatic charged particle beam lens converges a charged particle beam will be described. In FIG. 6, an R-axis extends in the radial direction of the lens, a J-axis extends in the optical axis direction, and “O” denotes the origin. FIG. 6 is a sectional view of an einzel lens taken along a plane parallel to the J-axis. The einzel lens includes three electrodes 3A, 3B, and 3C. The potential of the electrodes 3A and 3C are maintained at the ground potential, and a negative potential is applied to the electrode 3B. A charged particle beam has a negative charge. The three electrodes 3A, 3B, and 3C are flat plates each having the optical axis J as a normal line.

Electric flux lines generated in this state are illustrated by solid-line arrows H. The mid-planes of the three electrodes 3A, 3B, and 3C in the X direction and the mid-planes of spaces between the three electrodes are illustrated by broken lines. Intervals between broken lines along the J-axis will be referred to as an interval I, an interval II, an interval III, an interval IV. For convenience of describing the main lens effect of the einzel lens, it is assumed that an interval on the origin O side of the interval I and an interval in which J is larger than that in the interval IV are not provided with a potential.

The directions of electric fields in the interval I, the interval II, the interval III, and the interval IV in a region where R>0 are respectively indicated by arrows f1, f2, f3, and f4. The directions of the electric fields in the interval I, the interval II, the interval III, and the interval IV are respectively negative, positive, positive, and negative. Therefore, the path of a charged particle beam that passes an image height r0 is as indicated by arrow E. That is, the charged particle beam is diverged in the interval I, converged in the interval II, converged in the interval III, and diverged in the interval IV. This is optically equivalent to a concave lens, a convex lens, a convex lens, and a concave lens that are arranged in the J-axis direction.

The charged particle beam is converged for the following two reasons. A first reason is that, because a stronger force is applied to the charged particle beam at a larger image height, the effect of convergence in the interval II and the interval III is larger than the effect of divergence in the interval I and the interval IV. A second reason is that the charged particle beam travels in the interval II for a time longer than that in the interval I and travels in the interval III for a time longer than that in the interval IV. Because a change in momentum is equal to an impulse, a larger effect occurs on the electron beam in the intervals that take a longer time for the electron beam to travel.

The convergence effect is generated for the reasons described above. The charged particle beam is converged in a similar manner when a positive potential is applied to the electrode 3B. A charged particle beam having a positive charge is also converged. The convergence effect occurs for any combinations of the positive/negative potential of the electrode 3B and the positive/negative charge of the charged particle beam. If the symmetry of the convergent field is broken due to a shape error in the opening 2 that forms the electric fields in the intervals I to IV, the electrostatic lens has high order aberrations such as astigmatism. Therefore, it is necessary that the shape of the opening be accurately formed, because the aberration of the electrostatic charged particle beam lens is sensitively influenced by the shape error in the opening formed in the electrode.

Next, mechanisms with which the opening cross sections near the front surface of the electrode have large influences will be described.

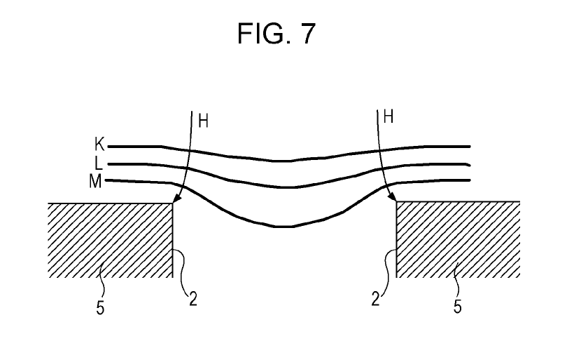

Referring to FIG. 7, the fact that the contribution of the shape of the opening to the aberration decreases as a position moves deeper in the opening from positions near surfaces of the first region 5 and the second region 7 such as positions at the openings 2A and 2C. FIG. 7 is an enlarged view of a region surrounded by broken line Z in FIG. 6. Curves K, L, and M represent equipotential lines in a space near a surface of an opening 2 in the electrode 3B. Curves H represent electric flux lines corresponding to an outermost surface of the opening 2. As illustrated in FIG. 7, the curves K, L, and M are substantially parallel to the surface of the electrode 3B in regions outside of the electric flux lines H (that is, on the sides on which the opening 2 is not formed). Therefore, the electric flux lines in this region are substantially parallel to a normal line of the electrode. Therefore, the influence of the shape of the electrode in this region on the electric fields in the R direction (see f1, f2, f3, and f4 in FIG. 6), which produce a lens effect, is negligibly small.

On the other hand, the equipotential lines K, L, and M are curved toward the inside of the opening 2 in regions on the sides of the electric flux lines H on which the opening 2 is formed (hereinafter referred to as “inside the electric flux lines H”). Therefore, the electric flux lines H and electric flux lines inside the electric flux lines H form the electric fields in the R direction, which produce a lens effect as described with reference to FIG. 6. Three-dimensionally, a charged particle beam is influenced by the electric fields in the R direction, which are illustrated in FIG. 6 and produce a lens effect, in all circumferential directions around the center of the optical axis J in a plane having the optical axis J as a normal line. The symmetries of the electric flux lines H and the electric flex lines inside the electric flux lines H in the circumferential direction (i.e. the circularity of a circular shape) around the optical axis J are influenced by the symmetry of the shape of a cross section of the opening 2 taken along a plane having the optical axis J as a normal line. The distances between the equipotential lines K, L, and M increase toward the optical axis J of the opening 2. The density of the electric flux lines decreases in a direction inward from the electric flux lines H and in a direction deeper in the thickness direction. Therefore, the sectional shape of the opening 2 at the outermost surface of the electrode influences most significantly to the convergence of a charged particle beam and the influence decreases as the depth in the thickness direction increases.

Here, the direction f2 of the electric field in the interval II of FIG. 6 has been described in detail. For the same reason, regarding each of the directions f1, f3, an f4 of the electric fields in the intervals I, III, and IV, the sectional shape of the opening 2 at the outermost surface of the electrode influences most significantly to the convergence of a charged particle beam. Therefore, the influence decreases with increasing distance from the outermost surface.

Even if the depth of the opening is increased, the contribution of the opening cross section near the surfaces does not change. That is, regardless of the thickness of the electrode in which the opening is formed, the aberration of the lens is considerably influenced by the shapes of the opening cross sections near the surfaces the electrode.

Portions of the opening near the surfaces of the electrode have shapes such that foreign substances and dust are most likely to adhere to the opening during the manufacturing process. In particular, the opening cross section at the outermost surface from which electric flux lines H illustrated in FIG. 7 enters is very likely to be subjected to such breakage or adherence of foreign substances.

With the charged particle beam lens according to the present invention, by disposing the openings 2A and 2B of the first region 5 and the second region 6, whose representative diameters are larger that that of the opening 2C, on at both ends of the opening 2C, even if breakage or adherence of foreign substances occurs on the opening cross sections of the opening 2A and 2B, the influence on the aberration of the lens can be restrained. Therefore, the yield of manufacturing the lens can be improved and the charged particle beam lens can be manufactured at low cost.

Next, the fact that the influence on the total astigmatism can be reduced by using a relationship between the representative diameters according to the present embodiment will be described. As illustrated in FIG. 2, the circularity of the sectional shape of the opening 2A is reduced due to the chip 15. However, because the opening 2C is not in contact with the outermost surface of the electrode because of the presence of the opening 2A, and the circularity of the opening cross section of this portion is not reduced due to the chip 15. When the representative diameters has a relationship such that D1>D2, the contribution of the opening 2A on the aberration of the lens can be reduced. Thus, the influence of the decrease in the circularity of the opening 2A on the aberration can be reduced.

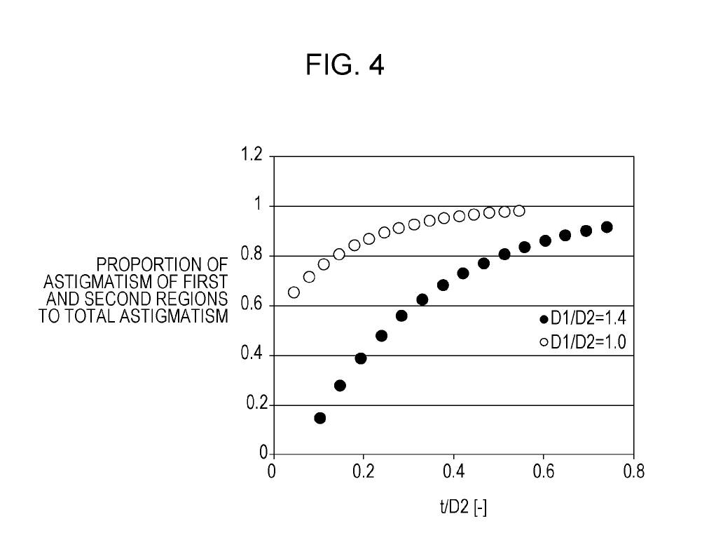

FIG. 4 illustrates the proportion (contribution) of the sum of the aberrations of the openings 2A and 2B in the astigmatism of the lens in the cases of FIGS. 2A and 2B. The horizontal axis represents the ratio of the diameter D2 and the thickness t of the openings 2A and 2B. Solid circles represent the case where the ratio between the diameters D1 and D2 is 1.4, and open circles represent the case where the diameters D1 and D2 are the same.

In the case where the diameters D1 and D2 are the same, the thickness t of the openings 2A and 2C is ⅛ of the diameter D1, and the sum of the aberrations of the openings 2A and 2C can occupy 80% of the total aberration. Because there is a small difference between the openings 2A and 2C, the contributions of the openings 2A, 2B, and 2C are 44%, 36%, and 20%, respectively.

Solid circles, which represent the case where the diameter D1 is 1.4 times D2, correspond to the embodiment of the present invention. Contribution of the openings 2A and 2B is smaller than that of the case where diameters D1 and D2 are the same. When the thickness t is ⅛ of the diameter D1, the contribution is about 35%. When the thickness t is ⅕ of the diameter D1, the contribution is 40%. Thus, if the diameters have a relationship such that D1>D2, contribution of the openings 2A and 2B on the aberration can be reduced with the same thickness t.

The relationship between the contributions does not change even when the thickness t′ of the opening 2C is changed. Therefore, by increasing the thickness of the opening 2C, the thickness and the rigidity of the entirety of the electrode can be increased while maintaining the relationship between the contributions. In this case, because the contribution of the openings 2A and 2B on the aberration is high, the influence on the aberration of the entirety of the lens can be reduced even if the opening 2B has a large manufacturing error.

Next, specific examples of the materials and the dimensions of the present embodiment will be described. The first, second, and third regions 5, 6, and 7 of each of the electrodes 3A, 3B, and 3C are made from monocrystalline silicon. The thicknesses of the first, second, and third regions 5, 6, and 7 are respectively 6 micrometers, 6 micrometers, and 90 micrometers. The diameters D1 of the openings 2A and 2B is 30 micrometers and the diameter D2 of the opening 2C is 22 micrometers. All of the first and second surfaces 8 and 9 and the inner walls of the openings 2A, 2B, and 2C of the electrodes 3A, 3B, and 3C may be covered by metal films. In this case, a metal such as a platinum metal that is resistant to oxidization or a molybdenum oxide having electroconductivity can be used. The electrodes 3A, 3B, and 3C are disposed so as to be separated from each other with a distance of 400 micrometers therebetween and so as to be parallel to a plane having the optical axis J and a normal line. The electrodes are electrically insulated from each other. The ground potential is applied to the electrodes 3A and 3C, and a potential of −3.7 kV is applied to the electrode 3B, so that the electrodes serve an einzel lens. An electron beam is used as a charged particle beam and the acceleration voltage is 5 keV. The circularity of the opening 2A and 2B is 9 nm, and the circularity of the opening 2C is 90 nm. However, the opening 2A has the chip 15, which is very small, and the average size of chips is about 50 nm.

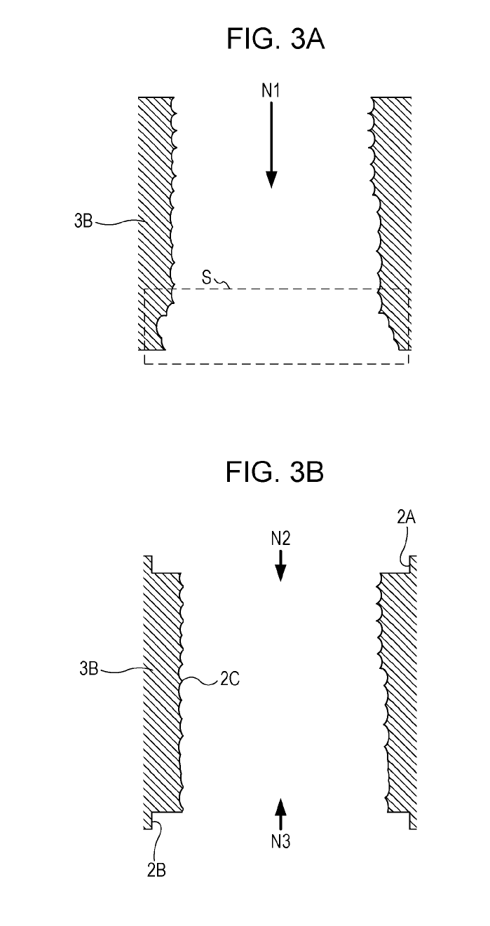

Next, method of manufacturing the present embodiment will be described. The first region 5, the second region 6, and the third region 7 are formed by performing etching three times. First, a hard mask made from chromium or an oxide film is formed on both surfaces of a silicon substrate having a thickness the same as that of an electrode so as to have a diameter the same as those of the openings 2A and 2B. An etching mask having a diameter the same as that of the opening 2C is formed by using a photoresist on a silicon substrate on a side on which the opening 2A is to be formed. As illustrated in FIG. 3A, a through-hole to become the opening 2C is formed in the direction of arrow N1 by using a mask made from a photoresist. Then, the photoresist is removed. Next, to form the openings 2A and 2B as illustrated in FIG. 3B, spot facing is performed by etching the substrate in the direction of arrows N2 and N3 by using hard masks. Thus, the first region 5, the second region 6, and the third region 7 can be formed.

In particular, it is known that, when forming a through-hole in a silicon substrate, notching occurs as illustrated by broken line S in FIG. 3A. This is a phenomenon in which the diameter of the opening is increased because the direction of ions and radicals used for etching fluctuated due to the presence of an interface in a direction in which the opening is being formed. If the notching occurs, the circularity of the opening cross section becomes worse in this portion. By performing large-diameter spot facing on both sides of as illustrated in FIG. 3B, this portion can be removed. As a result, the opening 2C, which has a large contribution to the aberration, can be formed with high precision.

### Second Embodiment

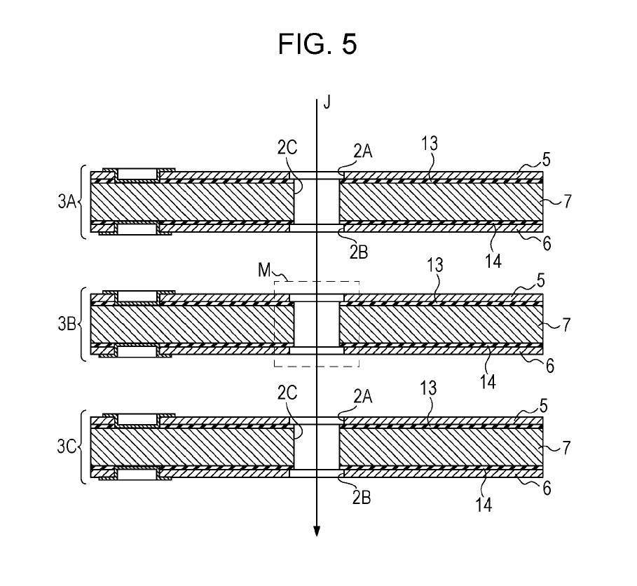

Referring to FIG. 5, a second embodiment of the present invention will be described. Portions having the same functions and effects as those of the first embodiment will be denoted by the same numerals and the description thereof will be omitted. The present embodiment is different from the first embodiment in that each of the electrodes 3A, 3B, and 3C has a bonded structure.

In each of the electrodes 3A, 3B, and 3C, the first region 5 and the third region 7, and the second region 6 and the third region 7 respectively bonded to each other at the interfaces with oxide films therebetween. The thickness of the first and second regions is 6 micrometers, and the thickness of the third region 7 is 90 micrometers.

Next, a method of manufacturing the present embodiment will be described. The first region 5, the second region 6, and the third region 7 are bonded to each other through the first interface 13 and the second interface 14. Silicon on insulator (SOI) substrates each having a device layer with a thickness of 6 micrometers, which are to become the first region 5 and the third region 7, an embedded oxide film layer, and a handle layer, are prepared. First, the openings 2A and 2B are formed in the device layers by performing high precision photolithography and dry etching of silicon. Subsequently, the entire substrate is thermally oxidized. The opening 2C is formed in a silicon substrate having a thickness of 90 micrometers, which is the same as that of the second region 6, by performing photolithography and deep dry etching of silicon. Then, the device layers of the SOI substrates, in which the opening 2A and 2B are formed, are directly bonded to the front and back surfaces of the silicon substrate in which the opening 2C is formed, through thermally oxidized films. Subsequently, by successively removing handle layers and embedded oxide film layers of the two SOI wafers and the thermally oxide films other than the bonding interfaces of the openings 2A and 2B, the electrodes 3A, 3B, and 3C each having the first region 5, the second region 6, and the third region 7 can be formed.

Due to the bonded structure described above, steps of forming openings in the first, second, and third regions can be independently performed. Therefore, by using semiconductor manufacturing technologies, fine and high precision openings can be formed while improving controllability of etching conditions and the yield. In particular, an electrode having a finer opening can be formed with high precision by using microfabrication technologies, such as photolithography or dry etching, and wafer bonding through silicon wafers having high degree of flatness. Moreover, the thicknesses of the first, second, and third regions can be precisely determined.

### Third Embodiment

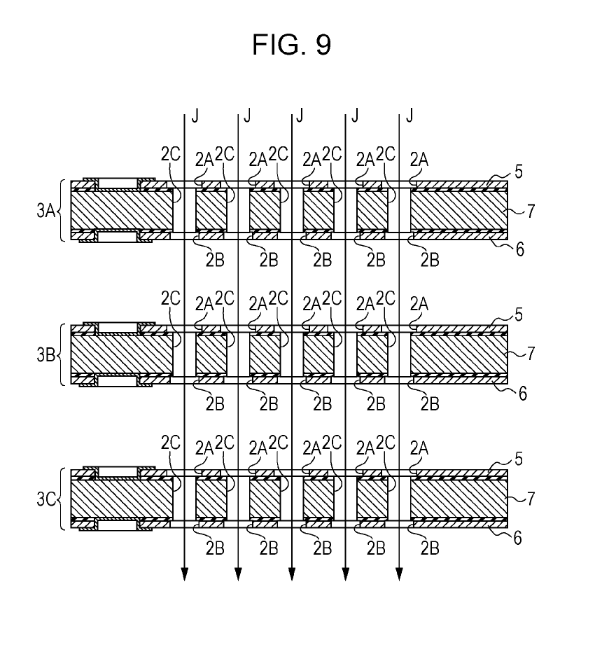

Referring to FIG. 9, a third embodiment of the present invention will be described. FIG. 9 is a sectional view of a charged particle beam lens. Portions having the same functions as those of the second embodiment will be denoted by the same numerals and description the effects the same as those of the first embodiment will be omitted. The present embodiment is different from the second embodiment in that each of the electrodes 3A, 3B, and 3C has a plurality of openings 2A, a plurality of openings 2B, and a plurality of openings 2C. In the present embodiment, as illustrated in FIG. 9, the charged particle beam lens is a lens array in which five openings are formed in each of the electrodes.

The diameters of the openings 2A and 2B are larger than that of the opening 2C. Because the diameter of the openings 2A and 2B are smaller than the pitch between adjacent openings, adjacent openings are not connected with each other in the first and second regions. Therefore, the lens array can be formed without reducing the rigidity of the entirety of the electrode.

In the case of a lens array, the openings are formed in a large area, and thereby the probability of chipping of the outermost surface and adherence of foreign substances may increase. However, with the present embodiment, the influence of such a defect on the aberration is reduced, so that variation in the aberration of the entirety of the lens can be reduced. Therefore, a large-scale lens array can be realized at low cost.

### Fourth Embodiment

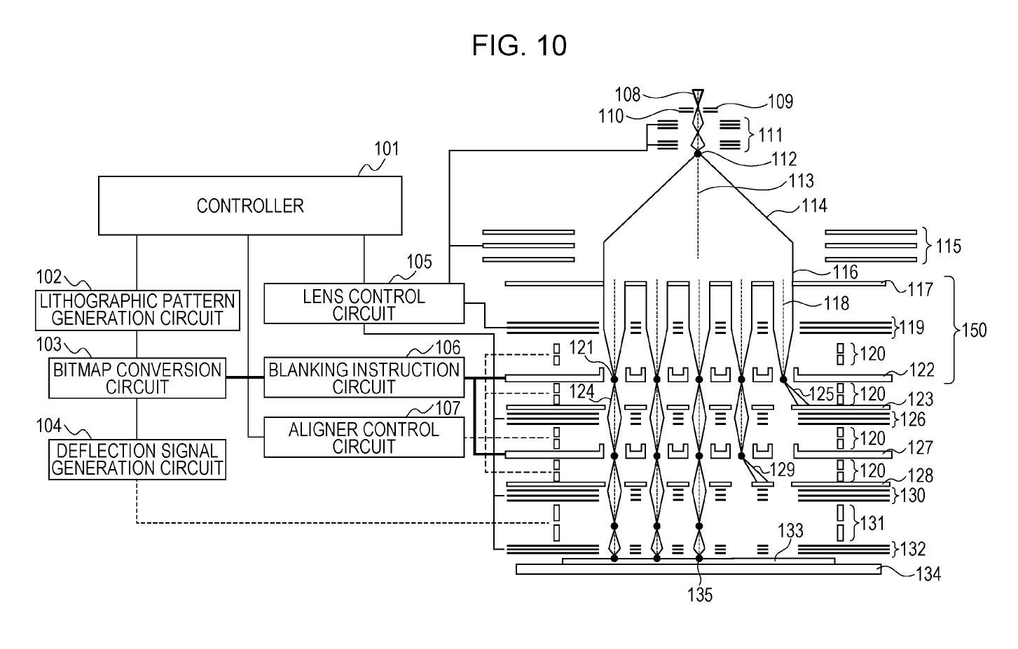

FIG. 10 illustrates a multi-charged-particle-beam exposure apparatus using a charged particle beam lens according to the present invention. The present embodiment is a so-called multi-column type having projection systems individually.

A radiation electron beam that is emitted from an electron source 108 through an anode electrode 110 forms an irradiation optical system crossover 112 due to a crossover adjusting optical system 111.

As the electron source 108, a so-called thermionic electron source using LaB6 or BaO/W (dispenser cathode) is used.

The crossover adjusting optical system 111 includes electrostatic lenses with two tiers. Each of the electric lenses in the first and second tiers is a so-called einzel electrostatic lens that includes three electrodes in which a negative voltage is applied to a middle electrode and the upper and lower electrodes are grounded.

The electron beam, which is spreads with a wide angle from the irradiation optical system crossover 112 is collimated by a collimator lens 115 and an aperture array 117 is irradiated with the collimated beam. The aperture array 117 splits the electron beam into multi-electron beams 118. A focusing lens array 119 individually focuses the multi-electron beams 118 to a blanker array 122.

The focusing lens array 119 is an einzel electrostatic lens array including three electrodes having multiple openings and in which a negative voltage is applied the middle electrode and the upper and lower electrodes are grounded.

The aperture array 117 is disposed at the position of the pupil plane of the focusing lens array 119 (the position of the front focus of the focusing lens array 119) so that the aperture array 117 may serve to define the NA (half-angle of focus).

The blanker array 122, which is a device having an independent deflection electrode, performs ON/OFF control of individual beams in accordance with a lithographic pattern on the basis of a blanking signal generated by a lithographic pattern generation circuit 102, a bitmap conversion circuit 103, and a blanking instruction circuit 106.

In a beam-ON state, a voltage is not applied to a deflection electrode of the blanker array 122. In a beam-OFF state, a voltage is applied to a deflection electrode of the blanker array 122, so that the multi-electron beams are deflected. A multi-electron beam 125 that has been deflected by the blanker array 122 is blocked by a stop aperture array 123 disposed behind the blanker array 122, so that the beam is cut off.

In the present embodiment, the blanker array has a two-tier structure in which a second blanker array 127 and a second stop aperture array 128 respectively having structures the same as those of the blanker array 122 and the stop aperture array 123 are disposed in the second tier.

The multi-electron beams that have passed through the blanker array 122 are focused on the second blanker array 127 by a second focusing lens array 126. Then, the multi-electron beams are focused by third and fourth focusing lenses to a wafer 133. As with the focusing lens array 119, each of the second focusing lens array 126, a third focusing lens array 130, and a fourth focusing lens array 132 is an einzel electrostatic lens array.

In particular, the fourth focusing lens array 132 is an objective lens having a reduction ratio of 100. Thus, an electron beam 121 on the intermediate imaging plane of the blanker array 122 (having a spot diameter of 2 micrometers at FWHM) is reduced to 1/100 on a surface of the wafer 133 to form an image of the multi-electron beam having a spot diameter of about 20 nm at FWHM. The fourth focusing lens array 132 is the charged particle beam lens array according to the second embodiment of the present invention.

Scanning of the multi-electron beam on the wafer can be performed by using a deflector 131. The deflector 131 includes four-tier counter electrodes, so that two-stage deflection in the x and y directions can be performed (for simplicity, two-tier deflectors are illustrated as one unit). The deflector 131 is driven in accordance with a signal generated by the deflection signal generation circuit 104.

While a pattern is being formed, the wafer 133 is continuously moved in the X direction by a stage 134. An electron beam 135 on the wafer is deflected in the Y direction by the deflector 131 on the basis of a real-time measurement result obtained by a laser length measuring machine. On/off control of the beam is individually performed by the blanker array 122 and the second blanker array 127 in accordance with the lithographic pattern. Thus, a desired pattern can be formed on the wafer 133 with a high speed.

By using the charged particle beam lens array according to the present invention, focusing having only a small aberration is realized. Therefore, a multi-charged-particle-beam exposure apparatus that can form a fine pattern can be realized. Moreover, the electrode may have a large thickness even if the openings through which multi-beams pass are formed in a large area, so that the number of the multi-beams can be increased. Thus, a charged particles beam exposure apparatus that forms a pattern with a high speed can be realized.

Moreover, because an inexpensive lens can be used, the exposure apparatus can be manufactured at low cost. Furthermore, because the exposure apparatus has a large tolerance regarding foreign substances or dust that adhere to the outermost surfaces during installation or in use, maintenance can be performed easily, frequency of maintenance can be reduced, and the reliability can be improved.

Even when the number of arrays in the lens array is increased and the area in which the openings are formed is increased, reduction in the yield of the lens array is prevented and thereby the exposure apparatus can be manufactured at low cost.

The charged particle beam lens array according to the present invention can be used as any of the focusing lens array 119, the second focusing lens array 126, the third focusing lens array 130.

The charged particle beam lens according to the present invention can be used as a charged particle beam lithography apparatus using a single beam instated of using a plurality of beams as illustrated in FIG. 10. Also in this case, by using a lens having only a small aberration, a charged particles beam exposure apparatus that forms a fine pattern can be realized.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-056814, filed Mar. 15, 2011, which is hereby incorporated by reference herein in its entirety.

1. An electrostatic charged particle beam lens comprising:
an electrode including a flat plate having a first surface having a normal line extending in a direction of an optical axis and a second surface opposite to the first surface, the electrode having a through-hole extending from the first surface to the second surface,
wherein, when an opening cross section is defined as a cross section of the through-hole taken along a plane perpendicular to the normal line and a representative diameter is defined as a diameter of a circle obtained by performing regression analysis of the opening cross section, a representative diameter of the opening cross section in a first region that is on the first surface side and a representative diameter of the opening cross section in a second region that is on the second surface side are each larger than a representative diameter of the opening cross section in a third region that is a region in the electrode disposed between the first surface and the second surface,
wherein, when an incircle and a circumcircle are respectively defined as two concentric circles having a smaller radius and a larger radius between which the opening cross section is disposed and having the smallest difference in the radii, a difference in the radii of the incircle and the circumcircle of the opening cross section in the first region and a difference in the radii of the incircle and the circumcircle of the opening cross section in the second region are each larger than a difference in the radii of the incircle and the circumcircle of the opening cross section in the third region, and
wherein the representative diameter in the first region and the representative diameter in the third region are different from each other at an interface between the first region and the third region, and the representative diameter in the second region and the representative diameter in the third region are different from each other at an interface between the second region and the third region.

2. (canceled)

3. The charged particle beam lens according to claim 1, wherein a thickness of each of the first region and the second region is smaller than a thickness of the third region.

4. The charged particle beam lens according to claim 1, wherein a thickness of the first region is smaller than ⅛ of the representative diameter in the third region and a thickness of the second region is smaller than ⅛ of the representative diameter in the third region.

5. The charged particle beam lens according to claim 1, wherein at least one of the first region and the second region is stacked on or bonded to the third region.

6. (canceled)

7. The charged particle beam lens according to claim 1, wherein the electrode is covered by an electroconductive film.

8. The charged particle beam lens according to claim 1, wherein the electrode has a plurality of openings.

9. An exposure apparatus comprising the charged particle beam lens according to claim 1 and using a charged particle beam.

10. The exposure apparatus according to claim 9 using a plurality of charged particle beams.
